(19) United States
(12) Patent Application Publication
(10) Pub. No.: US 2015/0293025 A1
(43) Pub. Date: Oct. 15, 2015

(54) METAL DOT SUBSTRATE AND METHOD OF MANUFACTURING METAL DOT SUBSTRATE

(71) Applicant: TORAY INDUSTRIES INC., Tokyo (JP)

(72) Inventors: Hirokazu Ninomiya, Otsu (JP); Yusuke Kawabata, Otsu (JP); Kiyohiko Ito, Otsu (JP); Yutaka Katayama, Otsu (JP)

(21) Appl. No.: 14/435,904

(22) PCT Filed: Dec. 11, 2013
(86) PCT No.: PCT/JP2013/083189

§ 371 Date: Apr. 15, 2015

(30) Foreign Application Priority Data
Dec. 18, 2012 (JP) 2012-275634
Jun. 3, 2013 (JP) 2013-116601

(51) Int. Cl. G01N 21/65; C23C 14/34; C23C 14/58; C23C 14/22; G01N 21/03; C23C 16/48

(52) U.S. Cl. CPC G01N 21/658; G01N 21/03; C23C 16/48; C23C 14/58; C23C 14/22; C23C 14/34

(57) ABSTRACT

A metal dot substrate includes metal-containing metal dots having a maximum outside diameter and height of 0.1 nm to 1,000 nm formed on a substrate and located in a plurality of island regions.

### TECHNICAL FIELD

This disclosure relates to a metal dot substrate that consists mainly of a substrate and nanometer-size metal dots formed thereon and a production method for such a metal dot substrate. “Metal dots” refer to metal-containing fine projections, particulates, quantum dots, and/or nanoclusters existing densely in a sufficiently small area and a “metal dot substrate” refers to one containing metal dots as defined above formed at least on one side of the substrate.

### BACKGROUND

In recent years, attention has been focused on application of metal dots and/or metal dot substrates to optoelectronic devices, light emitting materials, solar cell materials, electronic circuit boards or the like. Able to serve for concentration of electrons in a specific energy state, such metal dots have high value as chip material used for analysis by localized surface plasmon resonance (hereinafter abbreviated as LSPR) and also as chip material used for analysis by surface enhanced Raman scattering (hereinafter abbreviated as SERS) and low cost processes for metal dot production are an integral factor in the development of next generation devices.

Different studies have been made with the aim of developing a production method for such metal dots and/or metal dot substrates. For example, a thin metal layer is formed on a substrate by physical vapor deposition (hereinafter abbreviated as PVD) or by chemical vapor deposition (hereinafter abbreviated as CVD), followed by forming a resist layer. After prebaking, a required pattern is drawn by electron beam lithography (hereinafter abbreviated as EBL), followed by post-exposure baking and development to pattern the resist layer. The thin metal layer is patterned by dry etching using the patterned resist layer as a mask and, finally, the resist layer that covers metal dots is removed by appropriate treatment, for example, using a remover to expose the metal dots (see Japanese Unexamined Patent Publication (Kokai) No. 2007-218900).

In another process, a resist layer is formed on a substrate and then fine apertures are formed by a lithographic technique that uses exposure radiation of ultraviolet ray (UV), electron beam (EB) or the like. Subsequently, a thin metal layer is formed by PVD or CVD. Then, appropriate treatment is preferably by using, for example, a remover to remove the resist layer to form metal dots (see Japanese Unexamined Patent Publication (Kokai) No. 2010-210253).

In still another process, a thin metal layer is formed on a substrate by PVD or CVD and then metal dots are formed by annealing at a temperature lower than the melting points of the materials constituting the thin metal layer. In that production method, which is based on the SK (Stranski-Krastanov) mode, the thin metal layer is separated by the effect of strain energy and surface energy resulting from differences in lattice constants between the crystal base material constituting the substrate and the deposited crystal material that forms the thin metal layer and metal dots are formed through self-assembly after the separation of the thin metal layer (see Japanese Unexamined Patent Publication (Kokai) No. 2012-30340).

In comparison, if a plastic film is used as the substrate to carry metal dots, it serves to produce a flexible metal dot film that can be used on curved portions of electronic instruments or as material for electronic parts that need to be bent. If a plastic film wound on a roll is used, furthermore, a metal dot substrate can be produced through a roll-to-roll process so that a metal dot substrate can be produced continuously, leading to an advantage in terms of cost.

The methods designed to produce metal dot substrates using a generally known technique such as photolithography and EB lithography, however, involve complicated processes to form metal dots, leading to problems including unsuitability for mass production that can enable cost reduction and unsuitability of formation of fine structures because of limited resolutions. Japanese Unexamined Patent Publication (Kokai) No. 2012-30340 describes that the metal dot substrate production method includes a step of annealing at a temperature equal to or lower than the melting point of the thin metal film and shows an example in which a thin gold film (with a melting point of 1,063° C.) formed on a quartz substrate is annealed for 10 minutes at a high temperature of 700° C. in an electric furnace to form gold dots on the substrate. However, Japanese Unexamined Patent Publication (Kokai) No. 2012-30340 merely discloses a process in which a thin metal film formed on a heat-resistant substrate (quartz has a heat resistance of about 1,600° C.) is annealed at a very high temperature for a very long period, and there still remains the problem of the impossibility of application to substrates with a heat resistance of 700° C. or lower, such as plastic films.

It could therefore be helpful to provide a metal dot substrate that does not require a complicated process, is free from limitations on the heat resistance of the substrate material, and can be mass-produced at low costs and also provide a production method for the metal dot substrate.

### SUMMARY

We thus provide:

A metal dot substrate characterized by being a metal dot substrate having metal-containing metal dots formed on the substrate that are 0.1 nm to 1,000 nm both in maximum outside diameter and height and form a plurality of island regions.

A preferable example of the metal dot substrate is as follows:

(1) The substrate includes at least a plastic film.
(2) The plastic film has a thickness of 20 μm to 300 μm.
(3) The plastic film is a polyester film.
(4) The metal dot occupies 10% to 90% per unit area.
(5) The substrate includes an electrically conductive layer and/or a semiconductor layer.
(6) The production method includes a step of forming a thin metal film on the substrate and a step of applying an energy pulse beam to the substrate having the thin metal layer formed.
(7) The energy pulse beam used in the step of applying an energy pulse beam to the substrate having the thin metal layer formed is a beam in the visible light range emitted from a xenon flash lamp.
(8) The energy pulse beam used in the step of applying an energy pulse beam to the substrate having the thin metal layer formed is applied to an area having a size of 1 mm² or larger.
(9) The energy pulse beam used in the step of applying an energy pulse beam to the substrate having the thin metal layer formed has an irradiation energy of 0.1 J/cm² or more and 100 J/cm² or less.
(10) The energy pulse beam used in the step of applying an energy pulse beam to the substrate having the thin metal layer formed is applied for a total period of 50 microseconds or more and 100 milliseconds or less.
(11) The thin metal layer is formed by sputtering and/or deposition.
Furthermore, we provide an electronic circuit board in which the metal dot substrate is used.

We provide a metal dot substrate that does not require a complicated process, is free from limitations on the heat resistance of the substrate material, and can be mass-produced at low costs and also provide an electronic circuit board in which the metal dot substrate is used.

### BRIEF DESCRIPTION OF THE DRAWINGS

FIG. 1 is a cross section illustrating a typical structure of the metal dot substrate.

FIG. 2 is a cross section illustrating the substrate laminated with a thin metal film.

FIGS. 3 (a) and (b) are explanatory diagrams illustrating methods of applying an energy pulse beam to the substrate laminated with a thin metal film.

FIG. 4 is a typical spectrum of the energy pulse beam applied by a xenon flash lamp.

FIG. 5 is another typical spectrum of the energy pulse beam applied by a xenon flash lamp.

FIG. 6 is a HAADF-STEM image of the metal dot substrate prepared in Example 1 taken by a field emission type electron microscope.

FIG. 7 is a simplified diagram illustrating the roll-to-roll process used to produce the metal dot substrate in Example 4.

FIG. 8 (a) gives a photographed image and FIG. 8 (b) gives an enlarged image thereof illustrating the metal dots formed in Examples, photographed by a scanning electron microscope.

FIG. 9 (a) gives an oblique perspective diagram and FIG. 9 (b) gives a cross section illustrating a photoelectric conversion cell including a metal dot substrate produced in any of Examples 8 to 10.

### EXPLANATION OF NUMERALS

1: metal dot substrate
11: thin metal film-laminated substrate
2: metal dot
21: thin metal layer
22: simple metal dot
23: bipartite metal dot
24: moniliform metal dot
3: substrate
31: base layer
32: electrically conductive layer
33: semiconductor layer
4: light source
41: energy pulse beam
5: photoelectric conversion measuring cell
51: spacer
511: spacer's base
512: spacer's sticking layer
52: counter electrode
521: counter electrode's base
522: counter electrode's metal layer
53: liquid storage space, electrolyte
6: ammeter
7: energy pulse beam irradiation unit

### DETAILED DESCRIPTION

Our substrates and methods are described below with reference to the drawings.

### Substrate

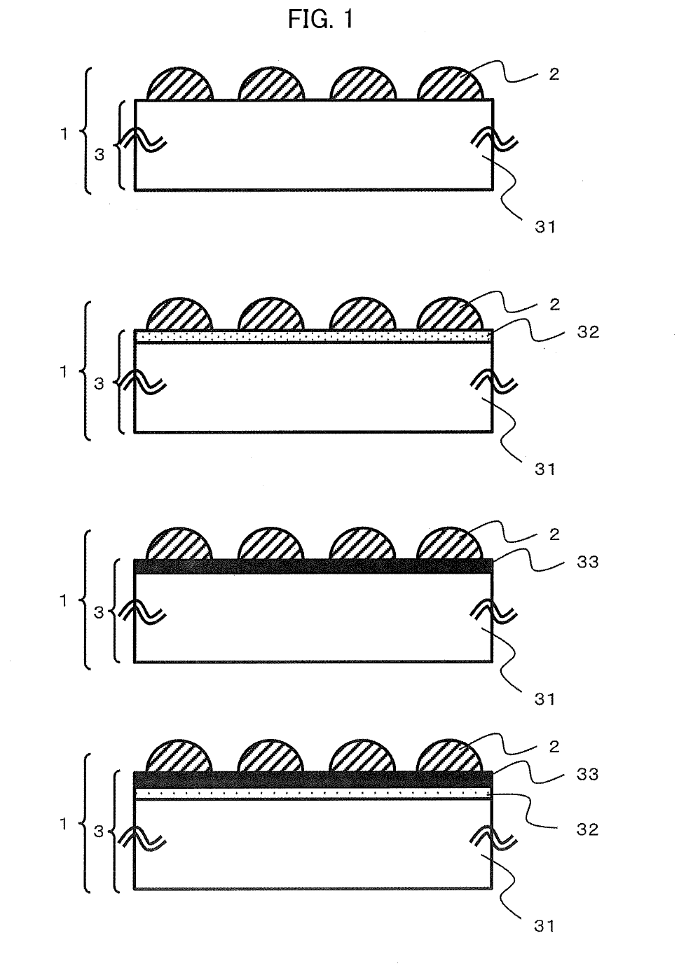

In FIG. 1, substrate 3 is preferably of an organic synthetic resin to permit mass production at low costs, but there are no specific limitations on its material, which may be selected from a wide range of substances including glass, quartz, sapphire, silicon, and metal. Useful organic synthetic resins include, for example, polyester, polyolefin, polyamide, polyester amide, polyether, polyimide, polyamide-imide, polystyrene, polycarbonate, poly-ρ-phenylene sulfide, polyether ester, polyvinyl chloride, polyvinyl alcohol, poly(meth)acrylate, acetate based material, polylactic acid based material, fluorine based material, and silicone based material. They also include copolymers, blends, and crosslinked compounds thereof. The material is preferably an organic synthetic resin, but there are no specific limitations, and it may be selected from a wide range of substances including glass, quartz, sapphire, silicon, and metal Useful organic synthetic resins include, for example, polyester, polyolefin, polyamide, polyester amide, polyether, polyimide, polyamide-imide, polystyrene, polycarbonate, poly-ρ-phenylene sulfide, polyether ester, polyvinyl chloride, polyvinyl alcohol, poly(meth)acrylate, acetate based material, polylactic acid based material, fluorine based material, and silicone based material. They also include copolymers, blends, and crosslinked compounds thereof.

Of the above organic synthetic resins, furthermore, preferable ones include polyester based, polyimide based, polystyrene based, polycarbonate based, poly-ρ-phenylene sulfide based, and poly(meth)acrylate based resins, of which polyester based synthetic resins, polyethylene terephthalate based ones in particular, are highly preferable from the viewpoint of their overall good properties including workability and economic efficiency.

Substrate 3 is preferably in the form of a film because it produces a flexible metal dot substrate that can be used on curved portions of electronic instruments or as material for electronic parts that need to be bent. The used of a film wound on a roll is preferable because the metal dot formation method can be performed in a roll-to-roll process so that a metal dot substrate can be produced continuously, leading to an advantage in terms of cost.

From the viewpoint of handleability and flexibility, the thickness of such a plastic film is preferably 20 μm to 300 μm, more preferably 30 μm to 250 μm, and still more preferably 50 μm to 200 μm.

Furthermore, the substrate 3 used in the metal dot substrate 1 may consist of a plurality of laminated layers of different materials or have a physically and/or chemically treated surface. For example, the substrate 3 may contain a base layer 31, an electrically conductive layer 32, and/or a semiconductor layer 33 so that the plasmon energy generated by the metal dots and light is converted into electric energy to provide electric power.

### Electrically Conductive Layer

There are no specific limitations on the electrically conductive layer 32 as long as it is of a material containing movable electric charges to transmit electricity. Specifically, any material should at least have an electric conductivity about equal to or higher than that of graphite (1×10⁶ S/m) and examples include metals and alloys of copper, aluminum, tin, lead, zinc, iron, titanium, cobalt, nickel, manganese, chrome, molybdenum, lithium, vanadium, osmium, tungsten, gallium, cadmium, magnesium, sodium, potassium, gold, silver, platinum, palladium, and yttrium, as well as electrically conductive polymers, carbon, graphite, graphene, carbon nanotube, fullerene, boron doped diamond (BDD), nitrogen doped diamond, tin doped indium oxide (hereinafter abbreviated as ITO), fluorine doped tin oxide (hereinafter abbreviated as FTO), antimony doped tin oxide (hereinafter abbreviated as ATO), aluminum doped zinc oxide (hereinafter abbreviated as AZO), gallium doped zinc oxide (hereinafter abbreviated as GZO), and other generally known materials. There are no specific limitations on the thickness of the electrically conductive layer 32 as long as it can transmit electricity smoothly and may be several nanometers to several millimeters. From the viewpoint of electric conductivity, handleability, and flexibility, it is preferably 1 nm to 300 μm, more preferably 3 nm to 100 μm, and still more preferably 10 nm to 50 μm. If the thickness is less than 1 nm, the resistance may be too high or a physical short circuit may occur during electric transmission, whereas if it is more than 300 μm, the handleability may decrease.

If transparency is required in specific applications, generally known transparent electrically conductive material such as, for example, ITO, FTO, ATO, AZO, GZO, carbon nanotube, graphene, and metal nanowire may be used appropriately. There are no specific limitations on the electrically conductive layer 32 as long as it can be stacked on the base layer 31 by a generally known method. Such generally known methods for lamination include, for example, bonding a metal foil of copper or aluminum to the base layer 31 with an adhesive and forming a layer on the base layer 31 by plating, sputtering, deposition, or coating with an electrically conductive paste and the like, followed by drying and, if required, calcination.

### Semiconductor Layer

There are no specific limitations on the material of the semiconductor layer 33. However, it is preferably one that can serve for photoelectric conversion. For example, metal oxides are preferred. Specifically, the use of one or more selected from the group consisting of, for example, titanium oxide (TiO₂), zinc oxide (ZnO), niobium oxide (Nb₂O₅), tin oxide (SnO), tungsten oxide (WO₃), strontium titanate (SrTiO₃), and graphene oxide (GO) is preferable from the viewpoint of the efficiency in photoelectric conversion. In particular, titanium oxide is preferable from the viewpoint of stability and safety. The titanium oxide may be in the form of one of various types of titanium oxide such as anatase type titanium oxide, rutile type titanium oxide, brookite type titanium oxide, amorphous titanium oxide, metatitanic acid, and orthotitanic acid, or may be in the form of titanium hydroxide or hydrous titanium oxide.

If titanium oxide is to be used as the material for the semiconductor layer, it is particularly preferable to adopt an anatase type titanium oxide because electrons can be obtained from more efficiently excited plasmon energy as the state density in the conduction band of titanium oxide increases.

There are no specific limitations on the thickness of the semiconductor layer 33 and it may be several nanometers to several millimeters. When used as photoelectric conversion material, it preferably has a thickness of 1 nm to 100 μm, more preferably 5 nm to 10 μm, and still more preferably 10 nm to 1 μm. If transparency is required in specific applications, it is preferably 300 nm or less, more preferably 100 nm or less.

There are no specific limitations on the semiconductor layer 33 as long as it can be stacked on the base layer 31 by a generally known method. For the stacking, generally known methods may be used including, for example, a method in which a metal foil containing metal such as copper, aluminum, titanium, and tin is subjected to surface oxidization treatment and bonded to the substrate with an adhesive and a method in which sputtering, deposition, or coating with metal alkoxide sol is performed for lamination.

Metal dot substrates produced by stacking the electrically conductive layer 32 and/or the semiconductor layer 33 on the base layer 31 can be applied to various devices including, for example, electronic circuit boards and quantum dot solar cells in which an optical electric field is strengthened by plasmon.

### Metal Dots

The metal dots 2 as referred to are metal-containing fine projections, particulates, quantum dots and/or nanoclusters, and metal-containing convex portions existing densely in a sufficiently small area, wherein the metal-containing convex portions mean convex portions formed of particles contained in the substrate and covered with metal or, on the contrary, metal film or metal particles fragmented by particles contained the substrate. The expression “metal dots existing in the form of islands” means that the dots exist independently (thus, even if they appear to be dots, they are not regarded as existing in the form of islands in the case of metal dots formed on a metal film to allow all of the metal dots to be connected though the metal film).

Each of the metal dots preferably has a size of 0.1 nm to 1,000 nm in both maximum outside diameter and height. There are no specific limitations on the shape of the metal dots as long as they are 0.1 nm to 1,000 nm in both maximum outside diameter and height.

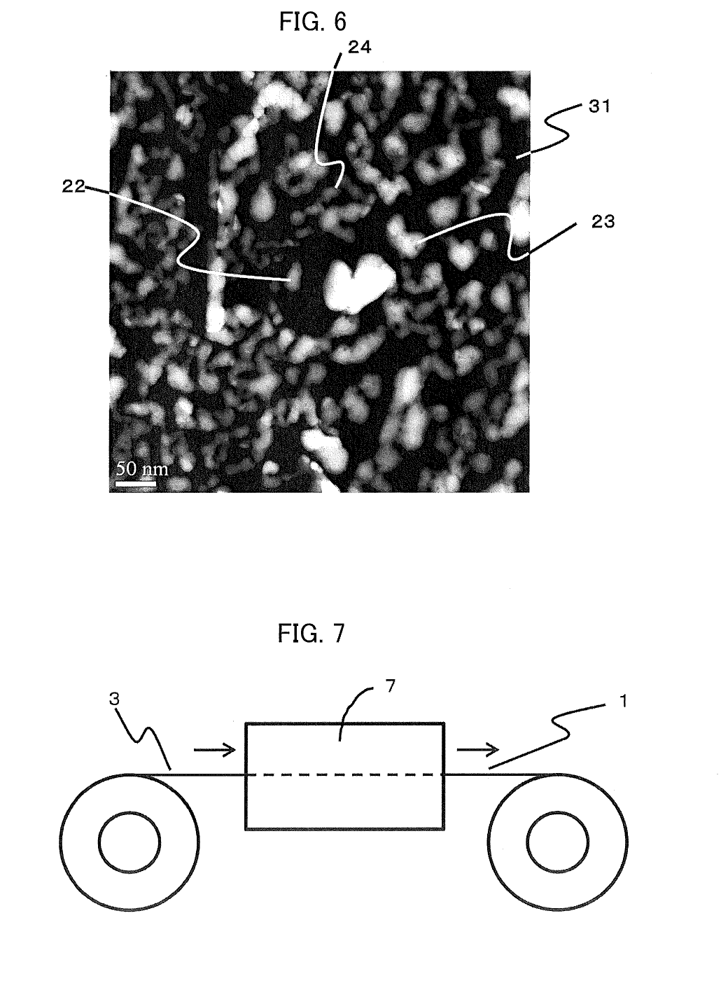

The maximum outside diameter of a metal dot referred to above is defined as the radius of the smallest circle that contains the whole metal dot when looked from right above. A region that appears to consist of a plurality of metal dots that are connected with each other (for example, the regions 23 and 24 in FIG. 6) is regarded as one metal dot and the radius of the smallest circle that contains the entire region is regarded as its maximum outside diameter. Furthermore, the expression “a metal dot being 0.1 nm to 1,000 nm in both maximum outside diameter and height” means the maximum value, minimum value, and average of the maximum outside diameter and height of the metal dot are all 0.1 nm to 1,000 nm.

The maximum outside diameter of the metal dots (the maximum outside diameter means the average of the maximum outside diameters of the metal dots) is preferably 0.1 nm to 1,000 nm, more preferably 1 nm to 100 nm. In addition, the height of the metal dots (the height means the average of the heights of the metal dots) is preferably 0.1 nm to 1,000 nm, more preferably 1 nm to 100 nm.

The metal dots 2 referred to above preferably occupy 10% to 90% of a unit area. If the occupation rate of the metal dots per unit area is less than 10%, the distances between the metal dots may be so large that the surface plasmon may not be sufficiently excited. If the occupation rate is more than 90%, on the other hand, the distances between the metal dots may be so small or the size of the metal dots themselves may be so large that the surface plasmon may not be sufficiently excited. From the viewpoint of the excitation of surface plasmon, the occupation rate is preferably 20% to 90%, more preferably 30% to 90%.

### Production Method for Metal Dot Substrate

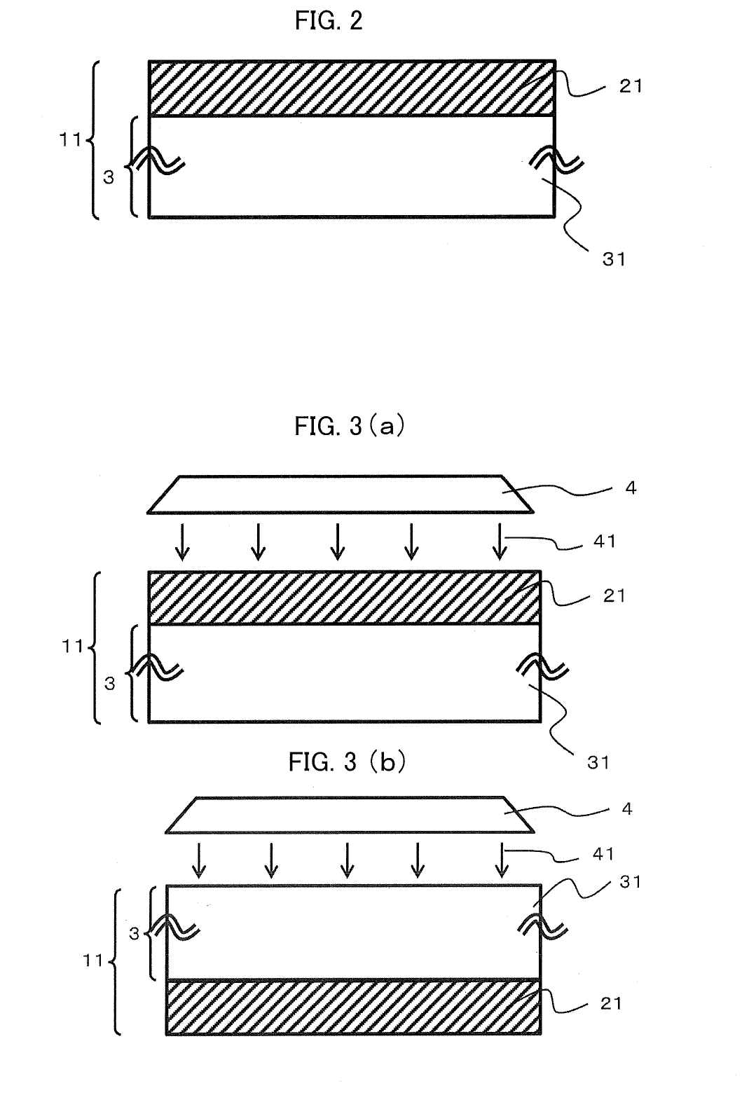

Described below is the production method for the metal dot substrate 1. The production method for the metal dot substrate 1 includes a step of preparing a substrate 3, a step of forming a thin metal layer 21 on the substrate (see FIG. 2), and a step of applying energy pulse beam 41 to the a metal film-laminated substrate 11 which has a thin metal film formed thereon (see FIGS. 3a and 3b).

### Formation of Thin Metal Layer

The step of forming the thin metal layer 21 can adopt sputtering and/or deposition to form the thin metal layer 21.

There are no specific limitations on the technique to be used for deposition, useful ones include, for example, PVD, plasma activated chemical vapor deposition (PACVD), CVD, electron beam physical vapor deposition (EBPVD) and/or metal organic chemical vapor deposition (MOCVD). These techniques are generally known and can serve to selectively produce a thin uniform metal-containing layer to cover a substrate.

Useful sputtering techniques include, for example, direct current (DC) diode sputtering, triode (or tetrode) sputtering, radio frequency (RF) sputtering, magnetron sputtering, facing target sputtering, and dual magnetron sputtering (DMS), of which magnetron sputtering is preferable because it serves to form a metal-containing layer rapidly on a relatively large substrate.

### Metal

There are no specific limitations on the material of the thin metal layer 21, and there are various useful metals. Useful ones include, for example, Al, Ca, Ni, Cu, Rh, Pd, Ag, In, Ir, Pt, Au, Pb, and other various ones, which may be used singly or as an alloy thereof to serve for specific applications. When applied to producing LSPR sensors or the like, the use of Ag or Au is particularly preferable because they give a specific peak in the visible light region.

The thin metal layer 21 preferably has a thickness of 0.1 nm or more and 100 nm or less. It is more preferably 0.5 nm or more and 50 nm or less, and more preferably 1 nm or more and 30 nm or less. If the thickness of the thin metal layer 21 is less than 0.1 nm, it may be sometimes difficult to form a thin film that contains metal uniformly and metal dots 2 may not be formed after a step of applying an energy pulse beam 41. If the thickness of the thin metal layer 21 is more than 100 nm, the thin metal layer 21 may have a dense structure and the thin metal layer 21 may have a gloss mirror surface. In such a case, a large part of the energy pulse beam 41 applied to the thin metal layer 21 may be reflected and the thin metal layer 21 may fail to absorb a required amount of energy in the step of applying the energy pulse beam 41, possibly failing to form metal dots 2 or leading to large metal dots 2.

### Energy Pulse Beam

The energy pulse beam 41 is a beam emitted from a light source 4 which is a laser source, xenon flash lamp, or the like, and in particular, it is preferable to use a beam in the visible light range emitted from a xenon flash lamp.

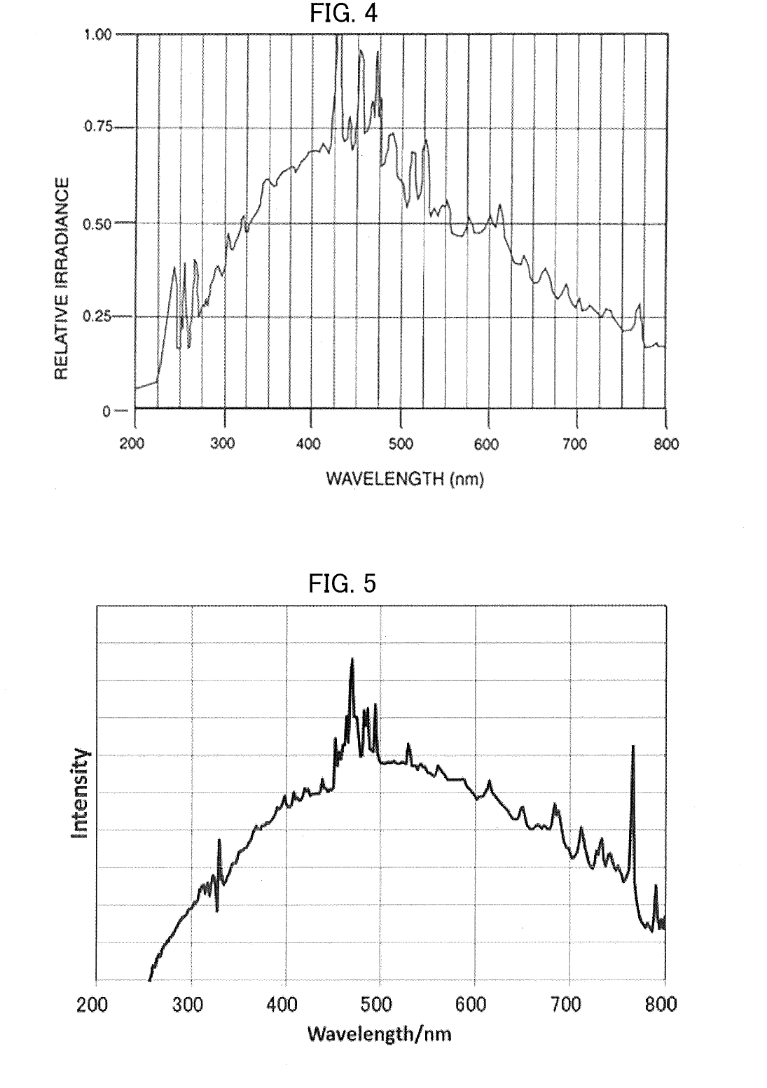

A xenon flash lamp consists mainly of a rod-like glass tube (electrical discharge tube) filled with xenon gas, an anode and a cathode provided at either of its ends and connected to a capacitor of a power source unit, and a trigger electrode provided on the circumferential surface of the glass tube. Xenon gas has electrically insulating properties and in a normal state, electricity does not flow through the glass tube even when electric charges are stored in the capacitor. If the insulation is broken by applying a high voltage to the trigger electrode, however, the electricity stored in the capacitor is discharged instantaneously in the glass tube between the electrodes located at both ends, and xenon atoms or molecules excited at this time emit a beam in the visible light range, that is, a flash light having a light spectrum of 200 nm to 800 nm. FIGS. 4 and 5 give typical spectra of the energy pulse beam 41 applied by a xenon flash lamp. In such a xenon flash lamp, electrostatic energy stored in advance in the capacitor is converted into an extremely short energy pulse beam about 1 microsecond to 100 milliseconds, making it possible to emit an extremely strong beam compared to continuous light sources. This means that application of the energy pulse beam 41 to the thin metal layer 21 allows the thin metal layer 21 to be heated quickly without causing a significant rise in the temperature of the substrate 3. Thus, heating the thin metal layer 21 lasts for only an extremely short time and it cools immediately after turning off the energy pulse beam 41, allowing metal dots 2 to be formed on the substrate 3. Although the mechanism involved has not been clarified yet, it is inferred that if the thin metal layer 21 is a continuous film, the thin metal layer 21 is separated as the thin metal layer 21 is heated by applying the energy pulse beam 41 and metal dots 2 are formed as a result of self-organization of the metal following the separation (so-called SK (Stranski-Krastnov) mode).

In the step of applying the energy pulse beam 41 to the thin metal film-laminated substrate 11 having the thin metal layer 21 formed thereon, the energy pulse beam 41 is commonly applied through the front surface of the thin metal layer 21 (FIG. 3a), but if the base layer 31 is of a transparent material, the energy pulse beam 41 may be applied through the rear surface of the substrate (the surface free of the thin metal layer 21) so that it reaches the thin metal layer 21 after passing through the base layer 31 (FIG. 3b).

There are no specific limitations on the size of the area irradiated with the energy pulse beam 41 in the step of applying the energy pulse beam 41 to the thin metal film-laminated substrate 11 having the thin metal layer 21 formed thereon, but the lower limit of the size of the irradiated area is preferably larger than 1 mm² or more, more preferably 100 mm² or more. No specific conditions are set up for the upper limit of the size of the irradiated area, but it is preferably 1 m² or less.

The productivity may decrease if the irradiated area exposed to the energy pulse beam 41 in each irradiation run is less than 1 mm². If it is 1 mm² or more, productivity will be high and an economic advantage will be ensured. If the irradiation area in each irradiation run is more than 1 m², the energy pulse beam irradiation equipment may have to contain many lamps arranged over a range and it may be necessary not only to use devices such as batteries and capacitors with large capacities for energy storage but also to equip them with large size ancillary components to assist instantaneous energy release.

For the step of applying an energy pulse beam 41 to the thin metal film laminated substrate 11, there are no specific limitations on the irradiation energy used to apply an energy pulse beam 41, but it is preferably 0.1 J/cm² or more and 100 J/cm² or less, more preferably 0.5 J/cm² or more and 20 J/cm² or less. If the irradiation energy is less than 0.1 J/cm², it may be impossible to form uniform metal dots 2 over the entire irradiated area. If the irradiation energy is more than 100 J/cm², the thin metal layer 21 may be evaporated by being heated excessively or the substrate 3 may be damaged by indirect heating from the heated thin metal layer 21. An economic disadvantage may also occur as a result of using an excess quantity of energy. If the irradiation energy is 0.1 J/cm² or more 100 J/cm² or less, it is preferable because uniform metal dots 2 can be formed over the entire irradiated area and it will be economically advantageous.

In the step of applying an energy pulse beam 41 to the thin metal film-laminated substrate 11, it is preferable to perform one or a plurality of irradiation runs to apply the energy pulse beam 41. Commonly, metal dots 2 can be formed in one irradiation run to heat the thin metal layer 21, but if required to ensure an intended irradiation area size or distribution or minimize the thermal damage on the substrate 3, the irradiation energy per run may be reduced and an appropriate rate (Hz) of irradiation per second may be set to allow irradiation (pulse irradiation) to be performed in a plurality of successive runs, thereby producing an intended metal dots substrate 1.

The energy pulse beam used in the step of applying an energy pulse beam 41 to the thin metal film-laminated substrate 11 having the thin metal layer 21 formed thereon is preferably applied for a total period of 50 microseconds or more and 100 milliseconds or less. It is more preferably 100 microseconds or more and 20 milliseconds or less, and more preferably 100 microseconds or more and 5 milliseconds or less. If it is less than 50 microseconds, it may be impossible to form metal dots 2 over the entire irradiated area. If it is more than 100 milliseconds, the thin metal layer 21 may be heated for an excessive period of time, thereby giving thermal damage to the substrate 3 or leading to a decrease in productivity. If the period is 50 microseconds or more and 100 milliseconds or less, uniform metal dots can be formed over the entire irradiated area, accordingly ensuring a high productivity and an economic advantage.

The step of applying an energy pulse beam 41 to the thin metal film-laminated substrate 11 can be carried out in a roll-to-roll process. Specifically, a film-like, thin metal film-laminated substrate 11 as shown in FIG. 7 may be unwound and allowed to pass through a unit 7 designed to apply an energy pulse beam 41 so that metal dots 2 are formed on the surface of the substrate to provide a film roll formed of the metal dot substrate 1 wound in a roll.

### Surface Plasmon

The metal dots substrate 1 can be used to produce a LSPR sensor, which uses LSPR, and an electrode substrate for a LSPR sensor.

In a LSPR sensor or the like as described above, surface plasmon is excited on the surface of the metal dots, which have a size about equal to or smaller than the wavelength of light so that their optical characteristics, such as absorption, transmission, and reflection, nonlinear optical effect, magnetooptical effect, and surface enhanced Raman scattered light are controlled or improved to serve as a sensor. It may be difficult to excite the surface plasmon if the metal dots are larger than the wavelength of light.

A plasmon is an oscillation wave of charge density generated by collective motion of free electron gas or plasma in bulk metal. A volume plasmon, that is, a plasmon of the common form, is a longitudinal wave, i.e. a dilatational wave and, therefore, cannot be excited by a light wave, i.e. an electromagnetic wave which is a transverse wave, but a surface plasmon can be excited by evanescent light (near-field light). This is because a surface plasmon is accompanied by evanescent light, which interacts with evanescent incoming light to excite plasma wave. From the viewpoint of the easiness of production, it is preferable to microminiaturize the metal to allow the incoming light to generate evanescent light that interacts with the evanescent light of the surface plasma.

### EXAMPLES

The production method for the metal dot substrate will be illustrated in detail below with reference to Examples.

### Measuring Methods for Maximum Outside Diameter of Metal Dots and Distance Between Metal Dots

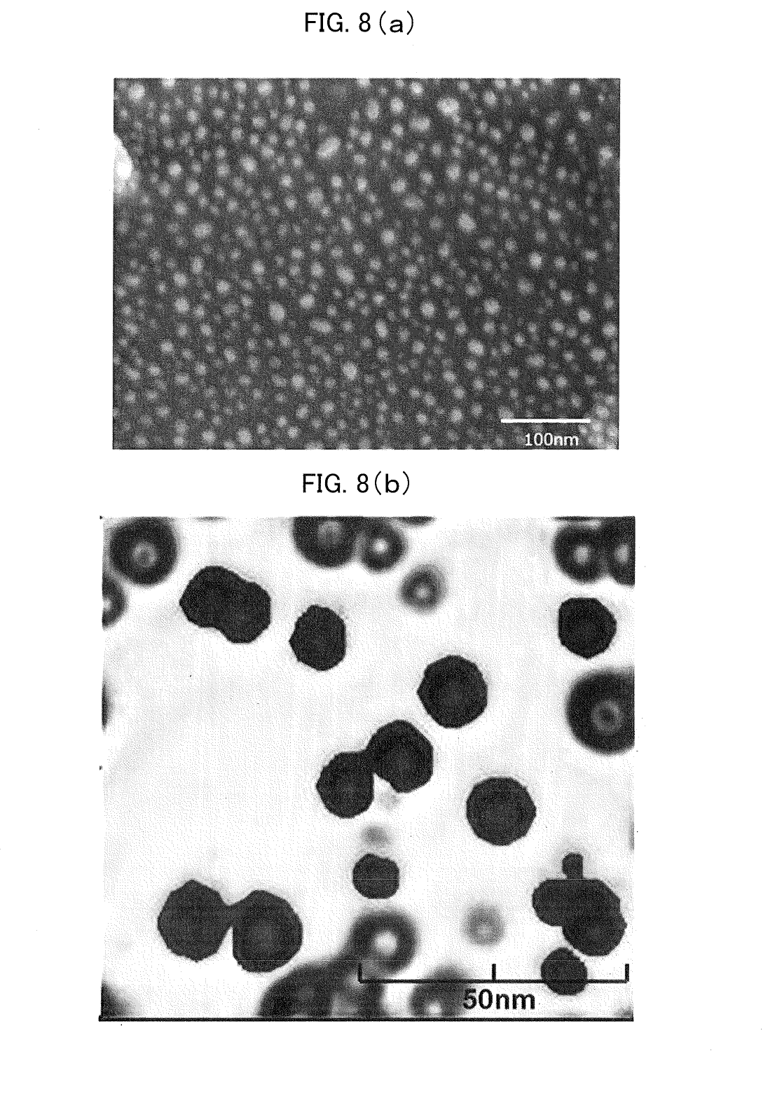

A scanning electron microscope (S-3400N, manufactured by Hitachi High-Technologies Corporation) was used to take secondary electron images (×200,000) that contain a 500 nm×500 nm area of the surface of a metal dot substrate (FIG. 8a). In this observation, each image had a size of 650 nm×500 nm consisting of 1,280 pixels×1,024 pixels, each pixel having a size of 0.48 nm×0.48 nm. A part of the photographed image equivalent to a size of 100 nm×100 nm was taken out (FIG. 8b) and SPM image analysis software (SPIP (trademark) supplied by Image Metorology A/S) was used to perform GRAIN-mode analysis. Ten metal dots were selected from the 100 nm×100 nm area of the photographed image and the maximum outside diameter of each of the ten metal dots and the distance between each pair of the metal dots were measured. When any of the metal dots was found to have a maximum outside diameter of more than 100 nm, another portion equivalent to a size of 500 nm×500 nm was taken out and a similar procedure was carried out to measure the maximum outside diameter and the distance between the metal dots. The maximum outside diameter of a metal dot is defined as the radius of the smallest circle that contains the whole metal dot when looked from right above. In respect to the maximum outside diameter, if a plurality of metal dots were found to be connected in pairs or in a moniliform manner, the largest radius that included a pair or a group was assumed to be its maximum outside diameter. In respect to the dot-to-dot distance among metal dots, if one arbitrarily selected metal dot was surrounded by a plurality of other metal dots, the distance from the outer edge of the arbitrarily selected metal dot to the outer edge of the nearest metal dot was measured as the dot-to-dot distance.

If one photographed image contained only less than 10 metal dots, additional images were photographed to take a total of 10 metal dots from a plurality of images. This procedure was repeated a total of 10 times and the measurements taken were averaged as shown in Table 1 (specifically, the maximum of the maximum outside diameter given in Table 1 is the average of the largest measurement in each of the ten runs and the average in Table 1 is the average of the total of 100 measurements (10 measurements×10 runs). Similarly, the minimum in Table 1 is the average of the smallest measurement in each of the ten runs).

Furthermore, a metal dot that partly stuck out of the 100 nm×100 nm area or 500 nm×500 nm area defined in a photographed image, it was not adopted as one of the 10 metal dots for measurement because parameter calculation was impossible for such a metal dot. Measuring method for occupation rate of metal dots

A scanning electron microscope (S-3400N, manufactured by Hitachi High-Technologies Corporation) was used to take secondary electron images (×200,000) that contain a 500 nm×500 nm area of the surface of a metal dot substrate. In this observation, each image had a size of 650 nm×500 nm consisting of 1,280 pixels×1,024 pixels, each pixel having a size of 0.48 nm×0.48 nm. A part of the photographed image equivalent to a size of 100 nm×100 nm was taken out and SPM image analysis software (SPIP (trademark) supplied by Image Metorology A/S) was used to perform GRAIN-mode analysis to calculate the occupation rate of the metal dots in the 100 nm×100 nm area. When any of the metal dots was found to have a maximum outside diameter of more than 100 nm, another portion equivalent to a size of 500 nm×500 nm was taken out and a similar procedure was carried out to calculate the occupation rate of the metal dots in the 500 nm×500 nm area. The “n” number adopted was 10 (which means that 10 samples were arbitrarily selected from photographed images of the surface of a metal dot substrate and the occupation rate was calculated for each of them, followed by determining the average of the 10 calculations as shown in Table 1).

### Measuring Method for Height of Metal Dots

An atomic force microscope (Dimension® Icon™ ScanAsyst, manufactured by BRUCEK) was used to observe the surface profile of a 100 nm×100 nm area of a metal dot substrate. When any of the metal dots was found to have a maximum outside diameter of more than 100 nm, another portion equivalent to a size of 500 nm×500 nm was defined in the metal dot substrate and its surface profile was observed. Ten metal dots were selected arbitrarily from the observed image and their heights were measured to calculate the maximum, minimum, and average of the height measurements. This procedure was repeated a total of 10 times and the measurements taken were averaged as shown in Table 1 (specifically, the maximum given in Table 1 is the average of the largest measurement in each of the ten runs and the average in Table 1 is the average of the total of 100 measurements (10 measurements×10 runs). Similarly, the minimum in Table 1 is the average of the smallest measurement in each of the ten runs).

### Example 1

A 50 mm×50 mm sheet of 100 μm biaxially stretched polyethylene terephthalate film (hereinafter referred to as PET) (Lumirror (registered trademark), Type T60, manufactured by Toray Industries, Inc.) was prepared as a substrate. Then, using 99.999 mass % platinum (Pt) as target, a thin Pt layer with a thickness of 10 nm was formed on a substrate in a sputtering apparatus (IB-3, manufactured by Elko Co., Ltd.). Subsequently, a 30 mm×30 mm area of the substrate was irradiated through the thin Pt layer using a xenon gas lamp LH-910 (manufactured by Xenon) designed to give a spectrum as shown in FIG. 4. A voltage of 2,500 V was stored in a capacitor and a high voltage was applied to the trigger to give an energy pulse beam to perform a 2-millisecond irradiation run. In this observation, the substrate was located 20 mm from the pulse beam source. Under the same irradiation conditions, the irradiation energy was measured with an energy meter (VEGA, manufactured by Ophir) and was found to be 5.0 J/cm².

### Example 2

A 50 mm×50 mm sheet of 50 μm polyimide film (hereinafter referred to as PI) (Kapton (registered trademark), Type H, manufactured by Du Pont-Toray Co., Ltd.) was prepared as a substrate. Then, using 99.999 mass % gold (Au) as target, the same sputtering procedure as in Example 1 was carried out to produce a thin Au layer with a thickness of 20 nm on a substrate. Subsequently, a 30 mm×30 mm area of the substrate was irradiated from the side free from the thin Au layer (exposed side of the substrate) with an energy pulse beam from a xenon gas lamp LH-910 (manufactured by Xenon). A voltage of 2,500 V was stored in a capacitor and a high voltage was applied to the trigger to perform 2-millisecond energy pulse beam irradiation runs repeated a total of 20 times with 5 second intervals. The irradiation energy used in this observation was measured and found to be 98.0 J/cm² in total.

### Example 3

A 50 mm×50 mm sheet of 188 μm cycloolefin copolymer film (hereinafter referred to as COP) (Zeonor (registered trademark), Type ZF16, manufactured by Zeon Corporation) was prepared as a substrate. Then, using 99.99 mass % silver (Ag) as target, the same sputtering procedure as in Example 1 was carried out to produce a thin Ag layer with a thickness of 3 nm on the substrate. Subsequently, a 30 mm×30 mm area of the substrate was irradiated with an energy pulse beam through the thin Ag layer using a xenon gas lamp LH-910 (manufactured by Xenon). A voltage of 2,500 V was stored in a capacitor and a high voltage was applied to the trigger to give an energy pulse beam to perform a 100-microsecond irradiation run. The irradiation energy used in this observation was measured and found to be 3.8 J/cm².

### Example 4

A 350 mm wide roll of 100 μm PET film (Lumirror (registered trademark), Type T60, manufactured by Toray Industries, Inc.) was prepared as a substrate. Then, using 99.9999 mass % copper (Cu), sputtering was performed in a roll-to-roll type magnetron sputtering apparatus (UBMS-W35, manufactured by Kobe Steel, Ltd.) to produce a thin Cu layer with a thickness of 50 nm. Subsequently, in a roll-to-roll process incorporating a pulse beam irradiation apparatus (Pulse Forge 3300, manufactured by Novacentrix in U.S.A.) designed to give a spectrum as shown in FIG. 5, an energy pulse beam was applied to a 150 mm wide region along the width center line of a 30 m long film, which was then wound in a roll. Specifically, a voltage of 800 V was stored in a capacitor and an irradiation run in which a 200 microsecond energy pulse beam with a pulse frequency of 20 Hz was applied to a 150 mm×75 mm area of the film, which was being conveyed at a speed of 9 m/min, was repeated 10 times. Under the same irradiation conditions, the irradiation energy was measured with an energy meter and found to be 25.2 J/cm².

### Example 5

A 50 mm×50 mm square of 100 μm PET film (Lumirror (registered trademark), Type U34, manufactured by Toray Industries, Inc.) was prepared as a substrate. Then, using 99.999 mass % platinum (Pt) as target, the same sputtering procedure as in Example 1 was carried out to produce a thin Pt layer with a thickness of 10 nm on the substrate. Subsequently, using a pulse beam irradiation apparatus (PulseForge 1200, manufactured by NoveCentrix) designed to give a spectrum as shown in FIG. 5, the substrate was irradiated through the thin Pt layer. A voltage of 450 V was stored in a capacitor and a 2 millisecond irradiation run was performed to apply an energy pulse beam to a 30 mm×30 mm area. Under the same irradiation conditions, the irradiation energy was measured with an energy meter and was found to be 7.7 J/cm².

### Example 6

Except for using 99.999 mass % silver (Ag) as sputtering target, the same irradiation procedure as in Example 5 was carried out.

### Example 7

Except for using a 50 mm×120 mm sheet of 100 μm thin plate glass (manufactured by Nippon Electric Glass Co., Ltd.), the same energy pulse beam irradiation procedure as in Example 5 was carried out to apply 2 millisecond irradiation to a 30 mm×30 mm area. In Examples 1 to 3 and 5 to 7, metal dots were formed successfully in a simple, low-cost process without limitations on the heat resistance of the substrate. In Example 4, we found that metal dot substrates can be produced in a roll-to-roll process, ensuring efficient mass production.

### Example 8

A 50 mm×50 mm sheet of 100 μm PET film (Lumirror (registered trademark), Type T60, manufactured by Toray Industries, Inc.) was prepared as a substrate. Then, ITO sputtering was carried out to form an electrically conductive layer 32 with a surface resistance of 300Ω/□. Subsequently, a titanium oxide sol solution (Type SLS-21, particle diameter 20 nanometers, manufactured by Ishihara Sangyo Kaisya, Ltd.) was applied with a spin coater and dried at 100° C. for 30 minutes. Then, using 99.999 mass % gold (Au) as target, the same sputtering procedure as in Example 1 was carried out to produce a thin Au layer with a thickness of 5 nm on the substrate. Subsequently, a 50 mm×50 mm area of the substrate was irradiated through the thin Au layer using a pulse beam irradiation apparatus (PF-1200, manufactured by NovaCentrix). A voltage of 350 V was stored in a capacitor and a high voltage was applied to the trigger to carry out a 1 millisecond irradiation run for applying an energy pulse beam to the Au layer. The irradiation energy used was measured with an energy meter and found to be 2.3 J/cm².

### Example 9

A 50 mm×50 mm sheet of 100 μm PET film (Lumirror (registered trademark), Type T60, manufactured by Toray Industries, Inc.) was prepared as a substrate. Then, ITO sputtering was carried out to form an electrically conductive layer 32 with a surface resistance of 300Ω/□. Subsequently, sputtering was carried out to form a 200 nm semiconductor layer 31 of niobium oxide. Furthermore, the same procedure as in Example 8 was carried out to form a 20 nm Au metal film. As in Example 8, a voltage of 350 V was stored in a capacitor and a 1.8 millisecond irradiation run was carried out to apply an energy pulse beam to the Au layer. The irradiation energy used was measured with an energy meter and found to be 3.8 J/cm².

### Example 10

A Pyrex (registered trademark) glass plate (manufactured by Tokyo Glass Kikai Co., Ltd.) with a diameter of 50 mm and a thickness of 2 mm was prepared as a substrate. Then, ITO sputtering was carried out to form an electrically conductive layer 32 with a surface resistance of 300Ω/□. Subsequently, a titanium oxide sol solution (Type SLS-21, particle diameter 20 nanometers, manufactured by Ishihara Sangyo Kaisya, Ltd.) was applied with a spin coater and dried at 100° C. for 30 minutes. Then, using 99.999 mass % silver (Ag) as target, the same sputtering procedure as in Example 1 was carried out to produce a thin Ag layer with a thickness of 8 nm on the substrate. Then, as in Example 8, a voltage of 300 V was stored in a capacitor and a high voltage was applied to the trigger to carry out a 1 millisecond irradiation run to apply an energy pulse beam through the Au layer to an area with a diameter of 50 mm. The irradiation energy used was measured with an energy meter and found to be 3.4 J/cm².

TABLE 1

| | | | | | Metal dots | | | | | | | |
|---|---|---|---|---|---|---|---|---|---|---|---|---|
| | | | | | | | | | | | Distance | Occu- |
| | | | | Irradiation | | | | | | | between | pation |
| | | | Thickness | energy | Maximum outside diameter (nm) | | | Height (nm) | | | metal dots | rate |
| | Substrate | Metal | (nm) | (J/cm²) | maximum | average | minimum | maximum | average | minimum | (nm) | (%) |
| Example 1 | PET film | Pt | 10 | 5.0 | 44 | 30 | 7 | 22 | 15 | 5 | 36 | 18 |
| Example 2 | PI film | Au | 20 | 98.0 | 48 | 39 | 16 | 35 | 29 | 10 | 59 | 66 |
| Example 3 | COP film | Ag | 3 | 3.8 | 20 | 18 | 5 | 8 | 6 | 1 | 15 | 20 |
| Example 4 | PET film | Cu | 50 | 25.2 | 87 | 56 | 20 | 90 | 72 | 30 | 10 | 65 |
| Example 5 | PET film | Pt | 10 | 7.7 | 69 | 53 | 23 | 20 | 16 | 4 | 17 | 31 |
| Example 6 | PET film | Ag | 10 | 7.7 | 113 | 74 | 48 | 21 | 14 | 6 | 24 | 36 |
| Example 7 | Glass | Pt | 10 | 7.7 | 76 | 64 | 24 | 19 | 13 | 3 | 22 | 40 |
| Example 8 | PET film/ | Au | 5 | 2.3 | 35 | 21 | 2 | 31 | 19 | 2 | 31 | 19 |
| | ITO/TiO₂ | | | | | | | | | | | |
| Example 9 | PET film/ | Au | 20 | 3.8 | 51 | 44 | 12 | 41 | 29 | 11 | 8 | 73 |
| | ITO/Nb₂O₅ | | | | | | | | | | | |
| Example 10 | Glass/ITO/ | Ag | 8 | 3.4 | 18 | 11 | 4 | 13 | 10 | 4 | 4 | 81 |
| | TiO₂ | | | | | | | | | | | |

The laminated metal dot films produced in Examples 2 and 6 to 10 were subjected to absorbance determination with a spectrophotometer (UV-3150, manufactured by Shimadzu Corporation) and results showed that absorption peaks attributed to surface plasmon resonance occurred at the wavelengths shown in Table 2.

TABLE 2

| | Absorbance peak | |
|---|---|---|
| | wavelength (nm) | Absorbance |
| Example 2 | 632 | 0.43 |
| Example 6 | 410 | 0.55 |
| Example 7 | 597 | 0.63 |
| Example 8 | 584 | 0.49 |
| Example 9 | 403 | 0.76 |
| Example 10 | 571 | 0.81 |

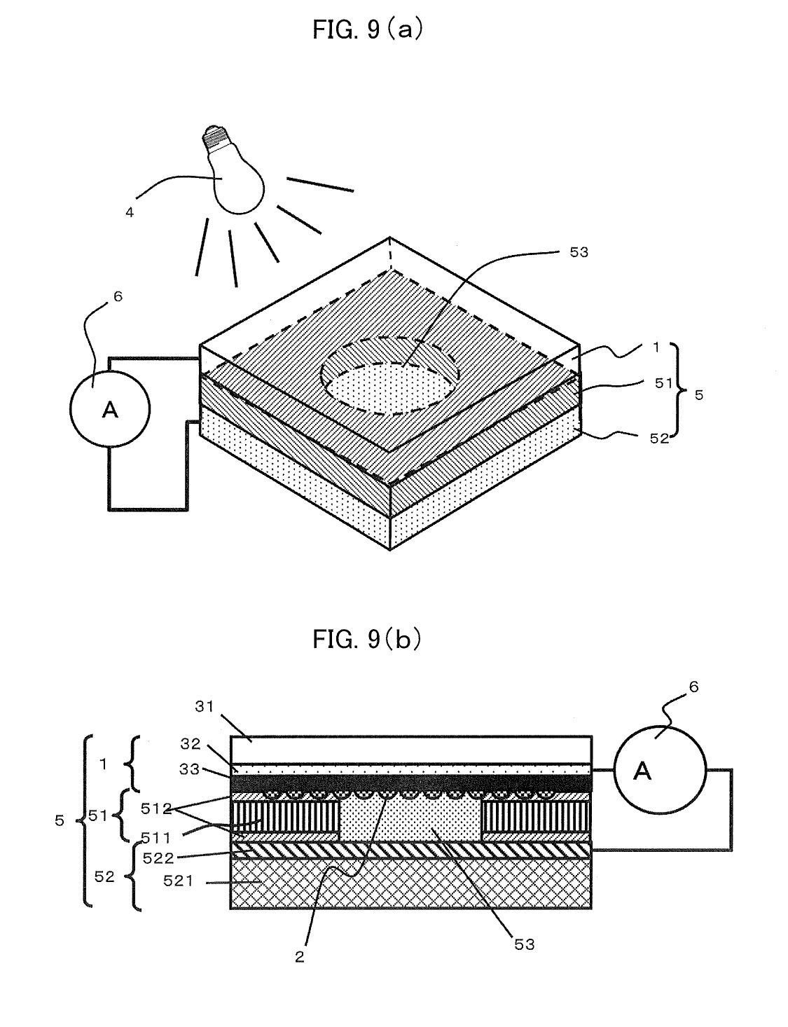

A cell was produced which comprised a metal dot substrate 1 prepared in any of Examples 8 to 10, a spacer 51 with a thickness of 140 μm consisting mainly of a spacer substrate 511, a sticking layer 512 provided on each side thereof, and a circular liquid storage space located in the central part thereof and designed to contain an electrolyte 53, and a counter electrode 52 consisting mainly of a counter electrode base 521 and a counter electrode metal layer 522 (Pt metal plate) with a thickness of 300 μm provided on one side thereof. Then, an electrolyte containing 0.1 M of iron sulfate heptahydrate, 0.025 M of iron sulfate (III) n-hydrate (n=6 to 9), and 1.0 M of sodium sulfate was injected in the liquid storage space 53 in the spacer 51 to produce a photoelectric conversion measuring cell 5 (FIGS. 9a and 9b).

Subsequently, a lead wire was put to the electrically conductive layer 32 in the metal-laminated substrate 1 and another lead wire was put to the metal layer 522 in the counter electrode 52, followed by connecting them to an ammeter 6.

Then, a light beam was applied to the metal-laminated substrate in the photoelectric conversion measuring cell 5 from a light source 4 (SS-200XIL, 2,500 W xenon lamp, irradiance 100 mW/cm², manufactured by EKO Instruments Co., Ltd.) and it was found that an electric current was produced as shown in Table 3.

TABLE 3

| | Electric current |
|---|---|
| | (μA/cm²) |
| Example 8 | 85 |
| Example 9 | 125 |
| Example 10 | 60 |

### Uses of Metal Dot Substrate

The production method for metal dots can provide uniform metal dot substrates and, accordingly, the resulting metal dot substrates can be used effectively in producing electronic device parts that require fine dot patterns. For example, such metal dots can be used as photoelectric conversion elements, which will serve as electrode members in solar batteries. Furthermore, fine metal dots can also be used to produce printing base material to print fine wiring patterns. In addition, such metal dots may be modified with ligands by, for example, bonding to DNA or protein substances that are reactive to specific enzymes, to produce LSPR sensors for biomolecular detection and electrode substrates for LSPR sensors.

In the production method of metal dots, furthermore, the application of an energy pulse beam serves to produce a metal dot substrate with an intended area size in a simple, quick process, leading to advantages in terms of production cost and environmental impacts and permitting application to a wide range of electronic instruments and optical devices.

### INDUSTRIAL APPLICABILITY

Metal dot substrates produced by the production method for metal dot substrates can be used in optoelectronic devices, luminescent materials, materials for solar batteries, and parts of various electronic devices such as electronic circuit substrates.

1.-13. (canceled)

14. A metal dot substrate comprising metal-containing metal dots having a maximum outside diameter and height of 0.1 nm to 1,000 nm formed on a substrate and located in a plurality of island regions.

15. The metal dot substrate as described in claim 14, wherein the substrate contains at least a plastic film layer.

16. The metal dot substrate as described in claim 15, wherein the plastic film layer has a thickness of 20 μm to 300 μm.

17. The metal dot substrate as described in claim 15, wherein the plastic film layer is a polyester film layer.

18. The metal dot substrate as described in claim 14, wherein the metal dots occupy 10% to 90% per unit area.

19. The metal dot substrate as described in claim 14, wherein the substrate contains an electrically conductive layer and/or a semiconductor layer.

20. A method of producing a metal dot substrate as described in claim 14 comprising forming a thin metal layer on a substrate and applying an energy pulse beam to the substrate having a thin metal layer formed thereon.

21. The method as described in claim 20, wherein the energy pulse beam used in applying an energy pulse beam to the substrate having a thin metal layer formed thereon is a beam in the visible light range emitted from a xenon flash lamp.

22. The method as described in claim 20, wherein applying an energy pulse beam to the substrate having a thin metal layer formed thereon irradiates an area with a size of 1 mm² or more with an energy pulse beam.

23. The method as described in claim 20, wherein applying an energy pulse beam to the substrate having a thin metal layer formed thereon uses an energy pulse beam having an irradiation energy of 0.1 J/cm² or more and 100 J/cm² or less.

24. The method as described in claim 20, wherein applying an energy pulse beam to the substrate having a thin metal layer formed thereon applies an energy pulse beam for a total time of 50 microseconds or more and 100 milliseconds or less.

25. The method as described in claim 20, wherein the substrate having a thin metal layer formed thereon is formed by sputtering and/or deposition.

26. An electronic circuit substrate comprising a metal dot substrate as described in claim 14.

27. The metal dot substrate as described in claim 16, wherein the plastic film layer is a polyester film layer.

28. The metal dot substrate as described in claim 15, wherein the metal dots occupy 10% to 90% per unit area.

29. The metal dot substrate as described in claim 16, wherein the metal dots occupy 10% to 90% per unit area.

30. The metal dot substrate as described in claim 17, wherein the metal dots occupy 10% to 90% per unit area.

31. The method as described in claim 21, wherein applying an energy pulse beam to the substrate having a thin metal layer formed thereon irradiates an area with a size of 1 mm² or more with an energy pulse beam.

32. The method as described in claim 21, wherein applying an energy pulse beam to the substrate having a thin metal layer formed thereon uses an energy pulse beam having an irradiation energy of 0.1 J/cm² or more and 100 J/cm² or less.

33. The method as described in claim 22, wherein applying an energy pulse beam to the substrate having a thin metal layer formed thereon uses an energy pulse beam having an irradiation energy of 0.1 J/cm² or more and 100 J/cm² or less.
